(19) United States
(12) Patent Application Publication
(10) Pub. No.: US 2025/0318164 A1
(43) Pub. Date: Oct. 9, 2025

(54) Insulated Gate Bipolar Transistor Having Improved Electrical Performance

(71) Applicant: ThinSiC Inc., Santa Clara, CA (US)

(72) Inventors: Tirunelveli Subramaniam Ravi, San Jose, CA (US); Jinho Seo, Saratoga, CA (US); Bishnu Prasanna Gogoi, Scottsdale, AZ (US)

(73) Assignee: ThinSiC Inc., Santa Clara, CA (US)

(21) Appl. No.: 18/628,735

(22) Filed: Apr. 7, 2024

(51) Int. Cl. H01L 29/739; H01L 29/16; H01L 29/66

(52) U.S. Cl. CPC H10D 12/441; H10D 12/031; H10D 12/032; H10D 62/8325

(57) ABSTRACT

Two or more IGBTs (insulated gate bipolar transistors) formed in or on a 4H silicon carbide (SiC) A-plane <1120> substrate of a first type. A merge layer is formed in the SiC substrate. The merge layer comprises an epitaxial layer of the first type formed by on-axis epitaxial lateral overgrowth. At least one epitaxial layer is formed overlying a surface of the merge layer. The at least one epitaxial layer is of a second type and at least 25 microns thick. The at least one epitaxial layer is formed by vertical epitaxial overgrowth. The at least one epitaxial layer is at least 25 microns thick and is a drift layer for the two or more IGBTs. An exfoliation process is configured to separate the SiC substrate at the merge layer from the two or more IGBTs. The SiC substrate is prepared and reused to form other semiconductor devices.

### FIELD

This invention relates to semiconductor device manufacture, and in particular to methods of forming an insulated gate bipolar transistor.

### BACKGROUND

The use of wide bandgap (WBG) semiconductors has increased dramatically in recent years in power electronics. Their ability to operate efficiently at higher voltages, powers, temperatures, and switching frequencies has enabled reduced cooling requirements, lower part counts, and the use of smaller passive components. WBG-based power electronics can further reduce the footprint and potentially the system cost of various renewable energy electrical equipment such as motor drivers and inverters.

Among the WBG semiconductors for power electronics, Silicon Carbide (SiC) has now been increasingly used for high voltage drivers (>1200V). From the substrate standpoint, 4H-Silicon carbide (SiC) Single Crystal Substrates have been used for both SiC and GaN devices since SiC and GaN epitaxial layers can be grown with reduced defects on SiC substrates. While the SiC substrate quality has dramatically improved in the recent years, the cost has not come down since substrate fabrication is a complex process starting with vapor phase ingot growth followed by ingot cropping, then wire sawing of individual wafers, and finally grinding and polishing of the substrate, and as of now, there has been no proven practical method to eliminate any of these foregoing steps.

As a semiconductor substrate for WBG semiconductors is being produced and devices that use high currents are fabricated, defects play a larger role and are magnified because die sizes are larger and any defect will contribute to more significant yield loss and potential lower reliability. Therefore, to maximize die yield, any cost reduction activity regarding the substrate and subsequent epitaxial layers formed on the substrate is paramount. Similarly, improving the electrical characteristics of the device formed on the substrate in conjunction with lowering fabrication costs will support integration into systems where they were not considered due to cost or performance. Furthermore, improving reliability of the device can be an essential component in utilizing a device where safety or critical operation is concerned. Improving device performance such as high frequency operation or increased voltage operation can also be a factor.

Accordingly, it is desirable to provide a system that lowers wafer processing costs while improving device performance to enable new uses for high power high efficiency semiconductor devices.

### BRIEF DESCRIPTION OF THE DRAWINGS

Various features of the system are set forth with particularity in the appended claims. The embodiments herein, can be understood by reference to the following description, taken in conjunction with the accompanying drawings, in which:

FIG. 1 is an illustration of the crystalline structure of the Silicon Carbide crystal in accordance with an example embodiment;

FIG. 2A is an illustration of the top view of an off-cut SiC wafer in accordance with an example embodiment;

FIG. 2B is an illustration of the side view of the off-cut SiC wafer in accordance with an example embodiment;

FIG. 3 is an illustration of a silicon carbide substrate (SiC) in accordance with an example embodiment;

FIG. 4 is an illustration of a hard mask layer overlying the silicon carbide substrate 300 in accordance with an example embodiment;

FIG. 5 is an illustration of a plurality of openings formed in the hard mask layer in accordance with an example embodiment;

FIG. 6 is an illustration of a plurality of openings formed in the silicon carbide substrate in accordance with an example embodiment;

FIG. 7 is an illustration of a plurality of pillars formed in the silicon carbide substrate in accordance with an example embodiment;

FIG. 8 is an illustration of a refill layer formed over the plurality of pillars and in the plurality of openings of FIG. 6 after removal of the patterned hard mask of FIG. 5 in accordance with an example embodiment;

FIG. 9 is an illustration of a mask layer formed between the plurality of pillars in accordance with an example embodiment;

FIG. 10 is an illustration of a merge layer formed in the silicon carbide substrate in accordance with an example embodiment;

FIG. 11 is an illustration of an epitaxial layer overlying the merge layer in accordance with an example embodiment;

FIG. 12 in an illustration of a current spreading layer in the epitaxial layer in accordance with an example embodiment;

FIG. 13 is an illustration of a body implant layer in the epitaxial layer in accordance with an example embodiment;

FIG. 14 is an illustration of an opening formed in the epitaxial layer in accordance with an example embodiment;

FIG. 15 is an illustration of an implant layer formed on the bottom of the trench in accordance with an example embodiment;

FIG. 16 is an illustration of source regions formed in the body implant layer is accordance with an example embodiment;

FIG. 17 is an illustration of an implant layer formed adjacent to the source regions in accordance with an example embodiment;

FIG. 18 is an illustration of a gate oxide and a gate electrode formed in accordance with an example embodiment;

FIG. 19 is an illustration of a dielectric isolation layer with a plurality of contact openings in accordance with an example embodiment;

FIG. 20 is an illustration of a plurality of metal contacts formed in accordance with an example embodiment;

FIG. 21 is an illustration of a carrier wafer attached to an IGBT formed in the silicon carbide substrate in accordance with an example embodiment;

FIG. 22 is an illustration of a portion of a silicon carbide substrate after an exfoliation process in accordance with an example embodiment;

FIG. 23 is an illustration of a back metal layer deposited in accordance with an example embodiment;

FIG. 24 is an illustration of the silicon carbide substrate with the IGBT after being separated from the carrier wafer in accordance with an example embodiment;

FIG. 25A is an illustration of the silicon carbide substrate after exfoliation in accordance with an example embodiment;

FIG. 25B is an illustration of a reclaimed silicon carbide substrate in accordance with an example embodiment; and

FIG. 26 is an illustration showing a block diagram of the formation of an IGBT in accordance with an example embodiment.

### DETAILED DESCRIPTION

The following description of embodiment(s) is merely illustrative in nature and is in no way intended to limit the invention, its application, or uses.

For simplicity and clarity of the illustration(s), elements in the figures are not necessarily to scale, are only schematic, are non-limiting, and the same reference numbers in different figures denote the same elements, unless stated otherwise. Additionally, descriptions and details of well-known steps and elements are omitted for simplicity of the description. Notice that once an item is defined in one figure, it may not be discussed or further defined in the following figures.

The terms “first”, “second”, “third” and the like in the Claims or/and in the Detailed Description are used for distinguishing between similar elements and not necessarily for describing a sequence, either temporally, spatially, in ranking or in any other manner. It is to be understood that the terms so used are interchangeable under appropriate circumstances and that the embodiments described herein are capable of operation in other sequences than described or illustrated herein.

Processes, techniques, apparatus, and materials as known by one of ordinary skill in the art may not be discussed in detail but are intended to be part of the enabling description where appropriate.

While the specification concludes with claims defining the features of the invention that are regarded as novel, it is believed that the invention will be better understood from a consideration of the following description in conjunction with the drawing figures, in which like reference numerals are carried forward.

This invention is related to silicon carbide (SiC) epitaxy as a Wide Band Gap (WBG) material for the fabrication of semiconductor devices and its application for formation of semiconductor devices such as IGBT (Insulated Gate Bipolar Transistor). In general, one or more epitaxial layers are grown overlying a silicon carbide substrate. The silicon carbide substrate can be a limiting factor in the performance and cost of the semiconductor devices as will be disclosed in more detail herein below. The use of Silicon Carbide as a material for semiconductor devices has grown significantly due to its unique properties for withstanding high voltages and high temperatures. Thus, SiC has been deployed for power devices since its breakdown voltage is about ten times higher than silicon and the thermal conductivity is about three time higher than silicon. The high breakdown voltages supports the development of high voltage devices such as SBDs (Schottky Barrier Diodes), MOSFETs (Metal Oxide Semiconductor Field Effect Transistors), BJT (Bipolar Junction Transistors) and IGBTs (Insulated Gate Bipolar Transistors) by reducing the thickness of the drift region and thereby reducing the RDSₒₙ, which is a key parameter for high voltage devices. Compared to silicon devices, SiC devices can operate at higher switching frequencies thereby reducing switching losses. Thus, SiC can be operated at higher temperatures due to better thermal conductivity and has higher heat dissipation for removing heat which are desirable device characteristics.

The Insulated Gate Bipolar Transistor (IGBT) is a power switching transistor that combines the advantages of MOSFETs and BJTs for use in power supply and motor control circuits. The IGBT structure incorporates both a MOSFET and BJT making it very suitable for a semiconductor switching device. The IGBT utilizes the advantages for the BJT and MOSFET f transistors and combines them to form a device with superior performance when compared to each device separately. The IGBT uses the high input impedance and high switching speed of a MOSFET and the low saturation voltage of a bipolar transistor and combines them to produce the IGBT switching device that can handle large collector-emitter currents with virtually zero gate current drive. More specifically, the IGBT combines the insulated gate of the MOSFET with the output performance characteristics of a conventional bipolar transistor. The result of this combination is that the IGBT is voltage controlled like a MOSFET but has the output switching and conduction characteristics of a bipolar transistor. IGBTs are typically used in high voltage and high speed switching applications. These devices require thick layers of silicon carbide grown epitaxially with high quality (low defect density) for their implementation.

As mentioned previously, semiconductor devices such as MOSFETs, SBDs, and IGBTs among others are formed by using Silicon Carbide wafers as the starting substrate on which various layers are grown using epitaxy growth processes.

The epitaxial growth process for SiC is quite complicated because of the crystalline structure of SiC which has an atomic crystal that comprises 50% Silicon and 50% Carbon. Each carbon atom has exactly four silicon atoms as neighbors and vice versa which results in a very strong C—Si bond strength of approximately 4.6 eV. The silicon carbide crystal has lattice sites which can differ in their structures of nearest neighbors of silicon and carbon atoms. For example, these lattice sites can be either hexagonal or cubic sites. Thus, for silicon carbide, H stands for hexagonal lattices sites while C stands for cubic lattice sites. Furthermore, cubic and hexagonal lattice sites differ in their number of second nearest neighbors which results in the different electric fields at the specific site.

In addition, silicon carbide as a material is an example for polymorphism, in which the SiC crystal can grow in a wide range of crystal structures, also known as the polytypes. Each polytype has different electrical, optical, thermal, and mechanical properties that depend on the specific crystal structure. In the hexagonal close packed system for silicon carbide, each polytype is defined by the Si—C bilayer stacking sequence along the c-axis. Thus, each polytype is labeled after the number of stacking Si—C bi-layers in the unit cell and the lattice structure. Some of the common polytypes for SiC are 3C-SiC, 2H-SiC, 4H-SiC, and 6H-SiC.

In one embodiment, for high power, high voltage, or high switching speed devices, the polytype that is selected is the 4H-SiC because of its superior electrical properties such as high breakdown voltage and high electron mobility. Moreover, it is possible to grow high quality, single crystalline 4H-SiC wafers of large diameter (up to 200 mm) with low defect concentrations. The process of producing SiC wafers starts with the growth of SiC bulk crystals (called boules) grown from a seed crystal using the sublimation growth method, typically along the [0001] direction. Since the growth rate of the bulk crystal of SiC is quite slow and prone to defects the usable length of the SiC boules are only between 30-50 mm. The process of producing SiC wafers from the SiC boules consist of slicing wafer that are sliced off-axis from the cylindrical boules. In one embodiment, the resulting off-axis 4H-SiC wafer is usually tilted 4 degrees towards the [1120] or [0001] direction to produce wafers with silicon carbide epitaxy with low defect density, as will be subsequently described.

For bipolar devices such as IGBTs, the quality of the epitaxy is critical from a device reliability perspective and requires careful consideration of the conditions for the growth of the required epitaxial layers. IGBTs and SiC bipolar transistors suffer from bipolar degradation where even a single basal plane dislocation can transform into a yield killing Single Stacking Fault (SSF) that is fatal for the electrical performance of the transistor device. SSFs between two partial dislocations are expanded during bipolar operation by gliding of partial dislocations leading to bipolar degradation and subsequent failure. By enabling growth of the epitaxial layers on the (1120) or A-plane of the 4H SiC substrate, basal plane dislocations can be avoided resulting in an epitaxial layer that is essentially defect free with high device reliability. While this approach is technically viable, the challenge is to implement this approach in a cost effective manner. Consequently, there is a need to produce high quality epitaxial layers for bipolar devices such as IGBTs that utilize the A-plane or (1120) with zero basal plane dislocations. In addition to using epitaxial layer growth in the A-plane, the same approach can be applied to substrates oriented in the M-plane (1100) and (1330) plane.

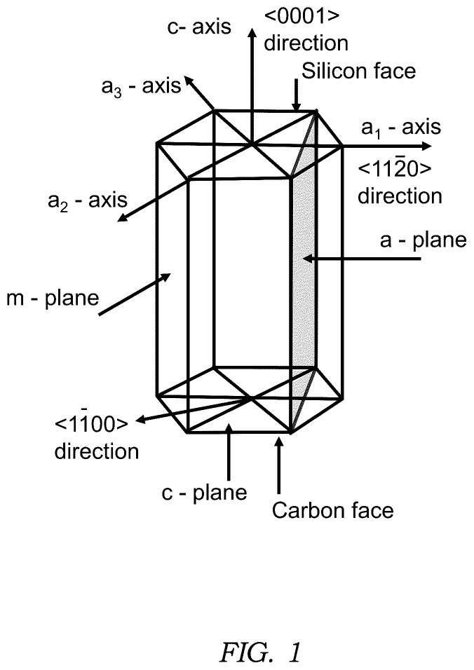

FIG. 1 is an illustration of the crystalline structure of the Silicon Carbide crystal in accordance with an example embodiment. The crystal planes and axis of the SiC crystalline structure is illustrated in FIG. 1 FIG. 1. The silicon facing face and the carbon facing face is at the top surface and bottom surface of the crystalline structure in FIG. 1. In addition, the a-plane, c-plane, and m-plane of the SiC crystal is also illustrated in FIG. 1. The orientation of the [1120] and [0001] directions used for the fabrication of the off-axis 4H-SiC wafer are also illustrated in FIG. 1.

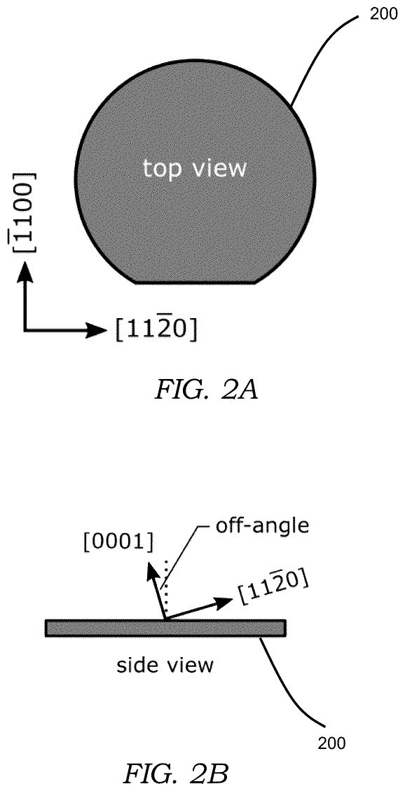

FIG. 2A is an illustration of the top view of an off-cut SiC wafer 200 in accordance with an example embodiment. Off-cut SiC wafer 200 is produced from a silicon carbide boule. The reference axis for the off-axis SiC (0001) wafer is also shown in FIG. 2A.

FIG. 2B is an illustration of a side view of the off-cut SiC wafer 200 in accordance with an example embodiment. Off-cut SiC wafer 200 is produced from a silicon carbide boule. The reference axis for the off-axis SiC (0001) wafer is also shown in FIG. 2B.

The figures subsequently describe an implementation of an IGBT in accordance with an example embodiment.

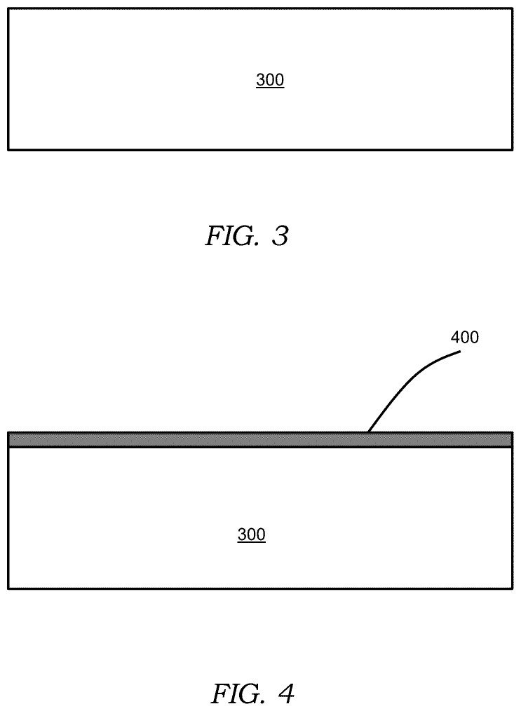

FIG. 3 is an illustration of a silicon carbide substrate (SiC) 300 in accordance with an example embodiment. In the example embodiment, silicon carbide substrate 300 is a silicon carbide wafer that is typically offcut by 4 degrees. Silicon carbide substrate 300 is used for the implementation of a semiconductor device such as an IGBT. In the example embodiment, silicon carbide substrate 300 is used to grow low defect density epitaxial layers for the implementation of IGBTs using a combined MOSFET and BJT (bipolar junction transistor) device structure. To improve the performance of the IGBT, silicon carbide substrate 300 comprises a silicon carbide wafer along the A-plane as referenced to the silicon carbide crystal. An A-plane substrate is normally not used due to cost. A method to reduce the silicon carbide substrate cost over many wafer fabrication cycles will be disclosed in detail herein below. The implementation of the IGBT using silicon carbide substrate 300 with the A-plane takes advantage of the enhanced surface mobility for the MOSFET structure as compared to the C-plane of the silicon carbide crystal. In general, silicon carbide substrate 300 comprises a 4H silicon carbide A-plane <1120> substrate used for the implementation of the IGBT. In one embodiment, silicon carbide substrate 300 comprises a p+ doped 4H silicon carbide A-plane <1120> substrate used for the implementation of the IGBT. In another embodiment, silicon carbide substrate 300 may comprise substrates in the M-plane (1100) and other planes such as (1330) plane. Although the example embodiment is illustrated with an IGBT, this invention may also be applied to other bipolar devices such as PIN diodes.

In one embodiment, silicon carbide substrate 300 may be a single side polished or double side polished wafer and can be considered as the parent wafer, for considerations that are described in subsequent process steps in the implementation of the current invention. In one embodiment, silicon carbide substrate 300 is the basic platform on which the example embodiment is implemented to support the process flow in accordance with the current invention. In one embodiment, silicon carbide substrate 300 is a reusable semiconductor substrate that is used for fabrication of semiconductor devices multiple times in accordance with the current invention.

It should be noted that more than one IGBT will be fabricated on silicon carbide substrate 300. The device structure shown in detail herein below will be replicated across silicon carbide substrate 300. In one embodiment, each IGBT will be diced as individual die and packaged as an individual device. A surface of silicon carbide substrate 300 will be prepared for reuse after the IGBT fabrication process. After preparation and repair of the surface the silicon carbon substrate can be reused in the manufacture of other devices or IGBTs.

FIG. 4 is an illustration of a hard mask layer 400 overlying silicon carbide substrate 300 in accordance with an example embodiment. Hard mask layer 400 is deposited over the surface of silicon carbide substrate 300. Hard mask layer 400 is deposited using techniques such as CVD (Chemical Vapor Deposition), LPCVD (low pressure chemical vapor deposition), PECVD (Plasma Enhanced Chemical Vapor Deposition), APCVD (Atmospheric Pressure Chemical Vapor Deposition), SACVD (Sub Atmospheric Chemical Vapor Deposition) among other techniques. PVD (Physical Vapor Deposition), or ALD (Atomic layer Deposition) may also be used for hard mask layer 400. In the example implementation, hard mask layer 400 comprises PECVD (Plasma Enhanced Chemical Vapor Deposition) silicon oxide. The thickness of silicon oxide hard mask layer 400 is selected based on the requirements of subsequent processing steps as described in the example implementation and is in the range of 100-3000 nm. The thickness of hard mask layer 400 is determined by the specific requirements of the implementation and is well known to one skilled in the art.

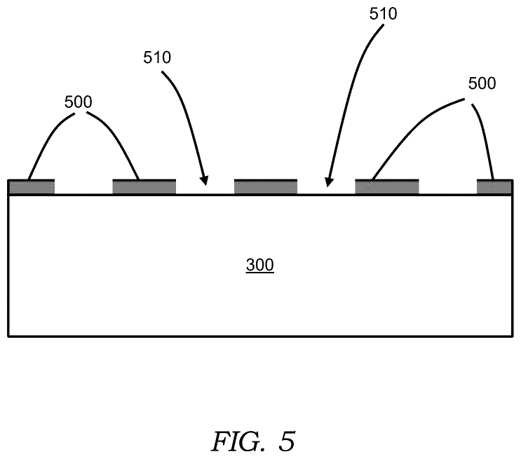

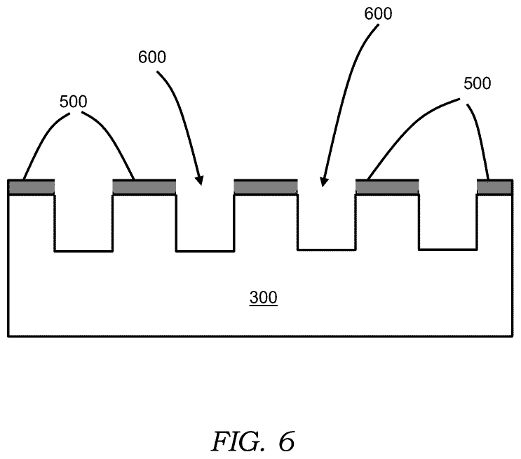

FIG. 5 is an illustration of a plurality of openings 510 formed in hard mask layer 400 of FIG. 4 in accordance with an example embodiment. In one embodiment, hard mask layer 400 of FIG. 4 is deposited overlying the surface of silicon carbide substrate 300 and is patterned to subsequently support the formation of plurality of openings 510 that expose areas of the surface of silicon carbide substrate 300. A remaining patterned hard mask 500 is formed after the patterning process. Plurality of openings 510 are formed in hard mask layer 400 of FIG. 4 by using methods of lithography and etching techniques commonly used in the semiconductor industry. In one embodiment, remaining patterned hard mask 500 is left in areas to protect silicon carbide substrate 300 from being etched. The shape of plurality of openings 510 are determined by the requirements of epitaxial growth in subsequent steps in the implementation of the example embodiment. In one embodiment, plurality of openings 510 may be in the shape of squares or rectangles. In another embodiment, plurality of openings 510 may be in the shape of triangles, hexagons, or diamonds. The size of plurality of openings 510 may be in the range of (20-500) nanometers (nm) and may be linearly arrayed or staggered and determined by the requirements of epitaxial overgrowth in the subsequent steps of fabrication of the example device. In one embodiment, spacing between adjacent openings of plurality of openings 510 is determined by the requirements of epitaxial overgrowth in the subsequent steps of fabrication of the example device and can be in the range of 500 nm to 5 micrometers (um). Plurality of openings 510 are generated on a surface of hard mask layer 400 of FIG. 4 by using lithography techniques that are well known to those skilled in the art. In one embodiment, plurality of openings 510 are implemented using optical lithography using UV, DUV or EUV. In another embodiment, plurality of openings 510 are implemented using an electron beam direct write technique. In yet another embodiment, plurality of openings 510 are implemented using Nano-Imprint Lithography (NIL).

In one example embodiment, plurality of openings 510 are implemented by first coating a surface of hard mask layer 400 of FIG. 4 with a photosensitive layer of photoresist, which may be positive or negative in its chemistry. In the example embodiment, positive photoresist is used in coating the surface of hard mask layer 400 of FIG. 4. An optical tool called a stepper is used to transfer the pattern of openings on to the positive photoresist layer using chemistries that are well known to those skilled in the art. The choice of the photoresist layer, thickness of the photoresist layer, the exposure and develop times for the subsequent chemical steps are well known to those skilled in the art and determined by the requirements of accurate pattern transfer from the photoresist layer to hard mask layer 400 of FIG. 4 to subsequently form plurality of openings 510 and leave patterned hard mask 500. The stepper transfers the pattern of plurality of openings 510 to cover the surface of hard mask layer 400 of FIG. 4 overlying silicon carbide substrate 300. In one embodiment, plurality of openings 510 cover an entire surface or substantially all of the surface of silicon carbide substrate 300.

After the pattern transfer is completed using lithography, the next step is the patterning of hard mask layer 400 of FIG. 4 using etching techniques to selectively remove the hard mask layer 400 of FIG. 4 overlying silicon carbide substrate 300 thereby leaving patterned hard mask 500 overlying silicon carbide substrate 300. The selective removal of hard mask layer 400 of FIG. 4 to form patterned hard mask 500 may use Reactive Ion Etching (RIE). Different gases may be used to form a plasma to selectively remove the portions of hard mask layer 400 of FIG. 4 exposed by the patterned photoresist. The choice of gases for the RIE is determined by hard mask layer 400 of FIG. 4 used in the implementation. In the example embodiment, with a silicon oxide used as hard mask layer 400, fluorine-based chemistries such as SF₆, CF₄, CHF₃, and other gases may be used in the RIE. Accordingly, in the example embodiment with silicon oxide as hard mask layer 400, plurality of openings 510 are etched in hard mask layer 400 of FIG. 4 using a fluorine-based chemistry that exposes the surface of silicon carbide substrate 300. Patterned hard mask 500 remains in areas overlying the surface of silicon carbide substrate 300 to protect or mask the surface of silicon carbide substrate 300 from etching. After patterning hard mask layer 400, the photoresist is stripped using techniques well known to those skilled in the art and may be dry, wet or a combination of dry and wet processing.

FIG. 6 is an illustration of plurality of openings 600 formed in silicon carbide substrate 300 in accordance with an example embodiment. Plurality of openings 600 are formed after hard mask layer 400 of FIG. 4 is etched to form plurality of openings 510 in FIG. 5. In one embodiment, the surface of silicon carbide substrate 300 exposed by plurality of openings 510 of FIG. 5 is then etched to form plurality of openings 600 using RIE (Reactive Ion Etching). In one embodiment, silicon carbide substrate 300 is etched using patterned hard mask 500 of FIG. 5 to form plurality of openings 600 with an aspect ratio that is determined by the requirements of epitaxial growth in subsequent processing of the example device. In one embodiment, an inductively coupled plasma (ICP) with high density may also be used to form plurality of openings 600 in silicon carbide substrate 300.

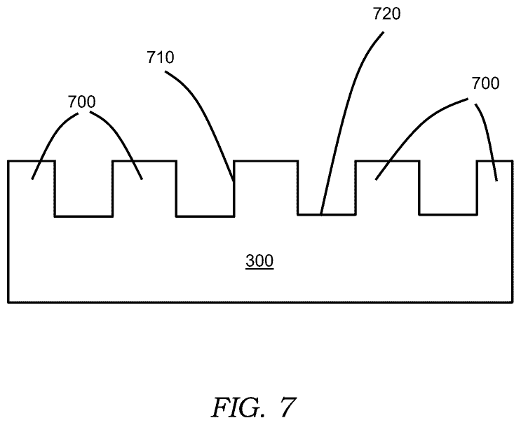

FIG. 7 is an illustration of a plurality of pillars 700 formed in silicon carbide substrate 300 in accordance with an example embodiment. Plurality of pillars 700 are shown after the removal of patterned hard mask 500 of FIG. 5. In an example embodiment, patterned hard mask 500 of FIG. 5 is removed by using wet or dry chemical etching and is determined by the choice of hard mask layer material. In the example embodiment, patterned hard mask 500 of FIG. 5 comprises a PECVD silicon oxide that is removed using a wet chemistry of BHF (Buffered Hydrofluoric Acid). Other solutions for etching PECVD silicon oxide may include HF (Hydrofluoric Acid) in various dilutions in water. Silicon carbide substrate 300 is then cleaned in preparation for the next step in the fabrication of the example device. In one embodiment, the pattern of plurality of pillars 700 are shaped as triangles or hexagons to expose (1120) or equivalent crystal planes since these orientations facilitate high quality epitaxial overgrowth with low defect density in subsequent processing steps in accordance with the current invention. In one embodiment, a height 710 of plurality of pillars 700 is in the range of (500-5000) nm and spacings 720 between adjacent pillars is in the range of (500-5000) nm and is determined by the requirements of silicon carbide epitaxy as subsequently described herein.

Subsequent figures disclosed herein below will describe an exfoliation process to separate one or more high quality epitaxial layers from silicon carbide substrate 300. In one embodiment, one or more semiconductor devices are formed in or on the one or more high quality epitaxial layers prior to implementing the exfoliation process. The separation of the one or more high quality epitaxial layers allows the reuse of silicon carbide substrate 300 in wafer processing of the formation of new semiconductor devices such as IGBTs. Alternatively, in one embodiment, there may only be need for a process to grow one or more high quality epitaxial layers attached to silicon carbide substrate 300 without exfoliation. The process for growing high quality epitaxial layers attached to silicon carbide substrate 300 will comprise a step of growing epitaxy by lateral epitaxial overgrowth on silicon carbide substrate 300 with plurality of pillars 700. In one embodiment, 4H-SiC growth will occur along the <1120> or <1100> directions due to the lateral epitaxial growth. In one embodiment, the lateral epitaxial overgrowth comprises growth from sidewalls of each pillar of the plurality of pillars 700. In one embodiment, lateral epitaxial overgrowth from the sidewalls from each pillar of the plurality of pillars 700 will merge comprising merged epitaxial lateral overgrowth (MELO) that is high quality low defectivity epitaxy. In one embodiment, the merged epitaxial lateral overgrowth (MELO) from the lateral epitaxial overgrowth process will form a continuous epitaxial layer overlying a vertical 4H-SiC growth in spacing 720 between plurality of pillars 700. This merged epitaxial lateral growth is possible by controlling height 710 of plurality of pillars 700 and spacings 720 between adjacent pillars in plurality of pillars 700 to form a high quality SiC epitaxial layer with low defect density. In one embodiment, silicon carbide substrate 300 comprises 4H silicon carbide A-plane <1120> substrate and the device fabricated on silicon carbide substrate 300 is a plurality of IGBTs (insulated gate bipolar transistors) overlying the epitaxial layer comprising MELO with a high quality and low defectivity.

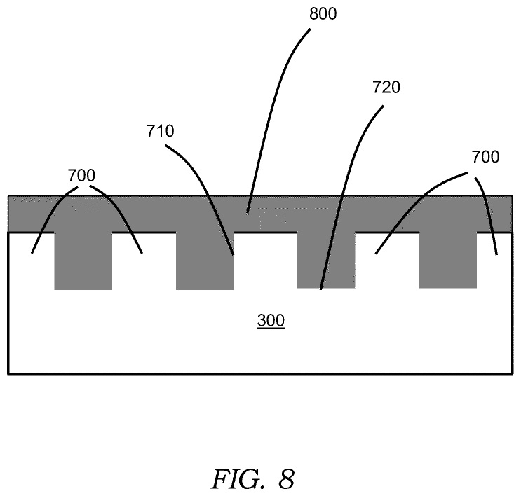

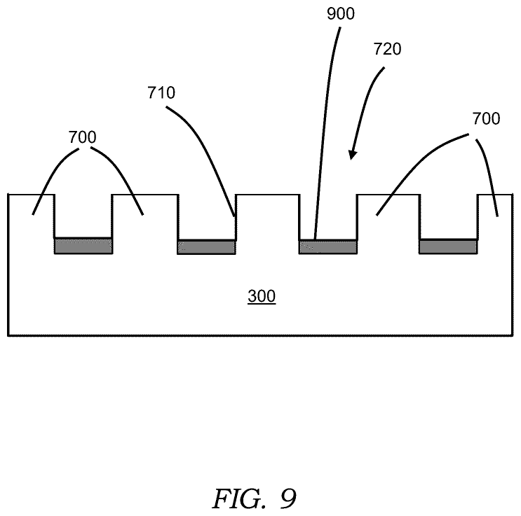

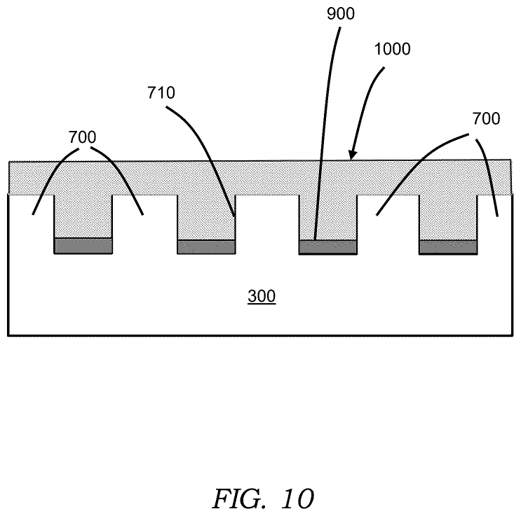

FIG. 8 is an illustration of a refill layer 800 formed over plurality of pillars 700 and in openings 600 of FIG. 6 after removal of patterned hard mask 500 of FIG. 5 in accordance with an example embodiment.

In one embodiment, refill layer 800 is formed overlying plurality of pillars 700 and in openings 600 after removal of patterned hard mask 500 of FIG. 5. In one embodiment, refill layer 800 is a carbon layer. In another embodiment, refill layer 800 is a polymer layer that is deposited and then subsequently converted into a carbon layer. In another embodiment, refill layer 800 is a tantalum carbide layer. In general, refill layer 800 is a layer that can subsequently be targeted specifically after further wafer processing is performed. For example, refill layer 800 can be selectively heated by laser in a subsequent step which will be described in further detail herein below.

Refill layer 800 can be formed over plurality of pillars 700 and in openings 600 after removal of patterned hard mask 500 using different methods and processes.

In one embodiment, refill layer 800 is formed by spin coating a polymer layer and then subsequently converting it into a carbon layer by pyrolysis in an inert environment. In another embodiment, refill layer 800 is formed by CVD (Chemical Vapor Deposition) of a polymer layer such as Parylene and subsequently converting the deposited polymer layer into carbon by heating it at a high temperature of (900-1400° C.) in an inert environment such as nitrogen. In another embodiment, refill layer 800 may be formed by sputter deposition using a carbon target. Other methods of carbon deposition may include CVD (chemical vapor deposition) or ALD (Atomic layer Deposition) to form refill layer 800.

In an example embodiment, refill layer 800 is formed by spin coating a photoresist layer. The photoresist layer may be a positive polarity or negative polarity photoresist. The choice of thickness of the photoresist layer is determined by the depth of plurality of pillars 700 and the final thickness of refill layer 800 required by the process. The final thickness of the spin-coated photoresist is determined by the choice of the viscosity of the photoresist and the spread and spin speed during the dispense of the photoresist. The spin-coated photoresist is then baked in a nitrogen environment at a temperature of (90-120)° C. to drive out solvents. In the pyrolysis process, silicon carbide substrate 300 having plurality of pillars 700 coated with a photoresist layer is placed in a furnace and heated to (900-1400° C.) in an inert environment of nitrogen or in forming gas (nitrogen with hydrogen) to convert the spin-coated photoresist to carbon. During the pyrolysis process, the spin coated photoresist layer is converted into carbon while undergoing volumetric shrinkage. In the example embodiment, the pyrolysis process converts the spin-coated photoresist to carbon while also shrinking to form refill layer 800. In another embodiment, the spin-coated photoresist layer thickness may be modified by etching in an oxygen plasma after the spin-coating and prior to the pyrolysis process.

FIG. 9 is an illustration of a mask layer 900 formed between plurality of pillars 700 in accordance with an example embodiment. Mask layer 900 is used in the epitaxial growth processes overlying silicon carbide substrate 300 as will be subsequently described herein below. In one embodiment, mask layer 900 is formed by reducing the thickness of refill layer 800 of FIG. 8 using an etching process. In one embodiment, refill layer 800 of FIG. 8 is a carbon layer and is etched using RIE (Reactive Ion Etching) to form mask layer 900. In one embodiment, a height of refill layer 800 is reduced to a predetermined height to form mask layer 900. In one embodiment, mask layer 900 is less than a height of each pillar of plurality of pillars 700. The predetermined height is achieved by RIE using oxygen, argon, and other gases, as well known to those skilled in the art. In one embodiment, the predetermined height of mask layer 900 is in a range of (300-1000) nanometers (nm).

FIG. 10 is an illustration of a merge layer 1000 formed in silicon carbide substrate 300 in accordance with an example embodiment. In the example embodiment, merge layer 1000 comprises an epitaxial layer formed by on-axis epitaxial lateral overgrowth over plurality of pillars 700 overlying mask layer 900 and silicon carbide substrate 300. Merge layer 1000 is an epitaxial layer with very low defectivity propagating from the surface of silicon carbide substrate 300. In one embodiment, merge layer 1000 is formed with very low basal plane dislocations (BPD) propagating from the surface of silicon carbide substrate 300 with 4H A-plane <1120> crystalline orientation. In addition, the density of defects is further reduced by lateral epitaxial overgrowth from the top surface of plurality of pillars 700 and sidewalls of plurality of pillars 700 resulting in an epitaxial layer comprising merge layer 1000 with extremely low density of defects making it suitable for formation of semiconductor devices such as IGBTs. In the formation of merge layer 1000, the epitaxial growth process between plurality of pillars 700 is inhibited by mask layer 900 such that the lateral epitaxial overgrowth is enabled from the top surface and sidewalls of plurality of pillars 700 resulting in a merging of epitaxial fronts from adjacent pillars of plurality of pillars 700. This results in the formation of a continuous epitaxial layer that is virtually free of basal plane dislocations as well as other crystal defects in silicon carbide epitaxial growth processes such as stacking faults, threading dislocations, edge dislocations among other defects. The merged epitaxial lateral overgrowth (MELO) results in formation of merge layer 1000 with very low density of defects making it suitable for formation of epitaxial layers for very high voltage semiconductor devices such as high voltage IGBTs. The extremely low defect density of defects in merge layer 1000 results in high reliability operation of high voltage semiconductor devices like IGBTs which are very sensitive to epitaxial defects in the epitaxial layers used in the fabrication of these devices. In one embodiment, merge layer 1000 comprises a p+ silicon carbide epitaxial layer formed by merged epitaxial lateral overgrowth plurality of pillars 700 and mask layer 900 overlying silicon carbide substrate 300 comprising a p+ silicon carbide wafer.

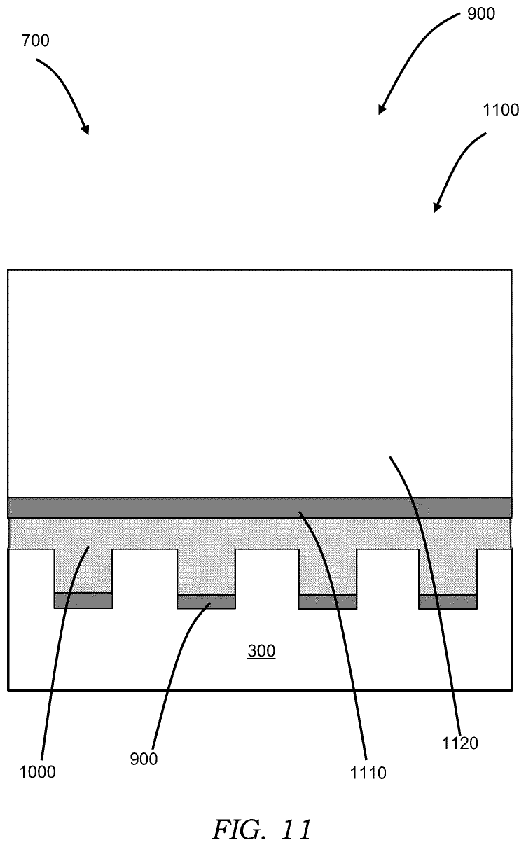

FIG. 11 is an illustration of an epitaxial layer 1100 overlying merge layer 1000 in accordance with an example embodiment. In the example embodiment, epitaxial layer 1100 is grown overlying merge layer 1000 to facilitate the formation of semiconductor devices such as IGBTs using suitable fabrication process. Epitaxial layer 1100 is grown overlying merge layer 1000 by vertical epitaxial growth in an epitaxial reactor. The thickness of epitaxial layer 1100 may be in the range of 20-200 microns and is determined by the performance requirements of the semiconductor devices formed in epitaxial layer 1100. Epitaxial layer 1100 may be doped either n-type or p-type based on the electrical device characteristics of the semiconductor devices formed in epitaxial layer 1100. In one embodiment, epitaxial layer 1100 may comprise two epitaxial layers which are sequentially grown overlying merge layer 1000 and has a different doping polarity from merge layer 1000. In one embodiment, epitaxial layer 1100 comprises epitaxial layer 1110 overlying merge layer 1000 and epitaxial layer 1120 overlying epitaxial layer 1110. In one embodiment, epitaxial layer 1110 comprises a n+ doped epitaxial layer forming a buffer layer overlying merge layer 1000 comprising a p+ doped epitaxial layer. In the example embodiment, merge layer 1000 comprises the p+ doped epitaxial layer overlying plurality of pillars 700 and merged from sidewall growth between adjacent pillars of plurality of plurality of pillars 700 thereby forming the merged lateral epitaxial lateral overgrowth (MELO). In the example embodiment, the p+ MELO epitaxial layer overlies mask layer 900 that overlies silicon carbide substrate 300 comprising a p+ doped silicon carbide wafer. In one embodiment, epitaxial layer 1120 comprises a n-doped epitaxial layer overlying the buffer layer comprising n+ doped epitaxial layer 1120. Epitaxial layer 1120 comprises a drift layer used for the formation of high voltage semiconductor devices such as IGBTs. The thickness of epitaxial layer 1120 may be in the range of 20-200 microns and is determined by the voltage requirements of the semiconductor devices formed in epitaxial layer 1100. In one embodiment, epitaxial layer 1120 is doped n-type and is about 100 microns thick for a IGBT operating above 10 KV.

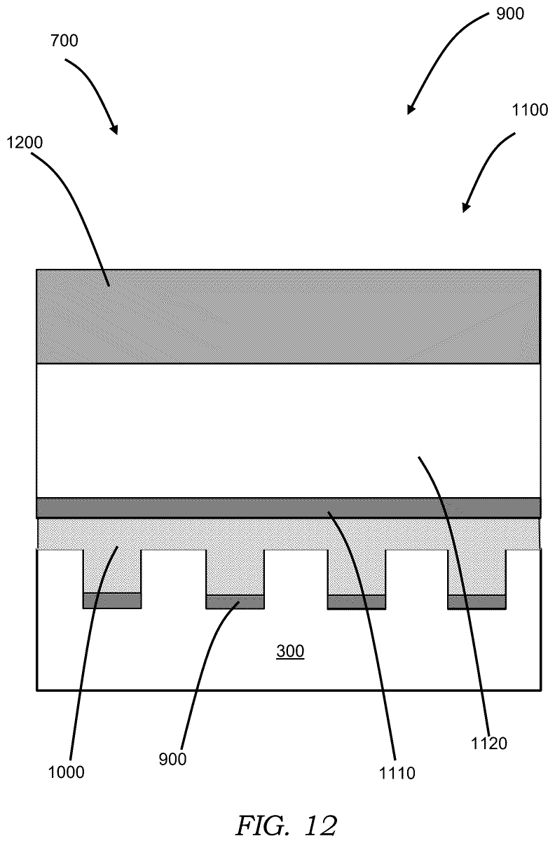

FIG. 12 in an illustration of a current spreading layer 1200 in epitaxial layer 1120 in accordance with an example embodiment. Current spreading layer 1200 is formed in epitaxial layer 1120 by implanting dopants into a surface of epitaxial layer 1120 and then subsequently activating the dopants by a furnace anneal. In one embodiment, the thickness of current spreading layer 1200 may be in the range of (0.1-3) micrometers and is determined by the electrical performance requirements of the semiconductor device that is formed in subsequent process steps. In the example embodiment, current spreading layer 1200 is meant to reduce the density of mobile carriers in the drift region and prevent current crowding by relaxing the concentration of the current distribution at the top of the drift region of the IGBT. The static and dynamic characteristics of the IGBT can be improved by adjusting the doping concentration of current spreading layer 1200 and also by adjusting the thickness of current spreading layer 1200.

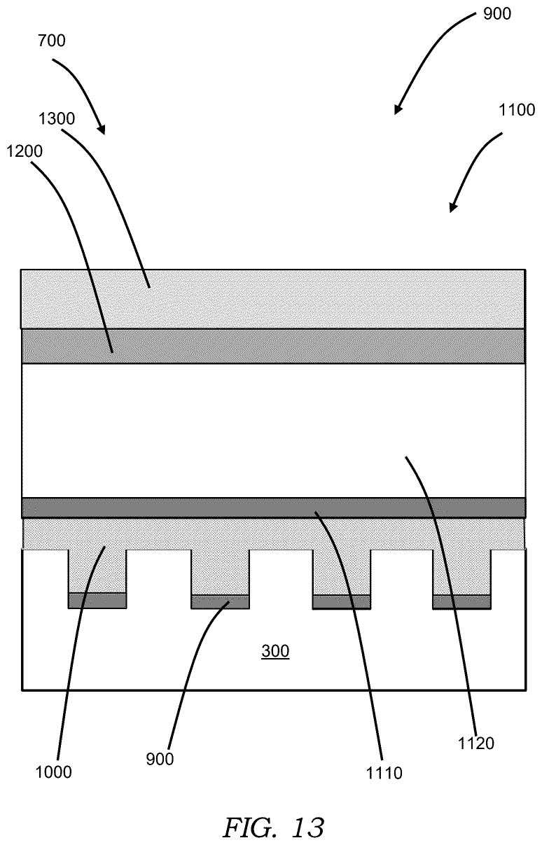

FIG. 13 is an illustration of a body implant layer 1300 in epitaxial layer 1120 in accordance with an example embodiment. Body implant layer 1300 is formed by epitaxial layer 1120 by implanting dopants of the opposite polarity to epitaxial layer 1120 and then activating the dopants. In the example embodiment, epitaxial layer 1120 is doped n-type and body implant layer 1300 is doped p-type. In the example embodiment, body implant layer 1300 is doped p-type to enable formation of a n-channel MOSFET of a IGBT with a n-type doped epitaxial layer 1120.

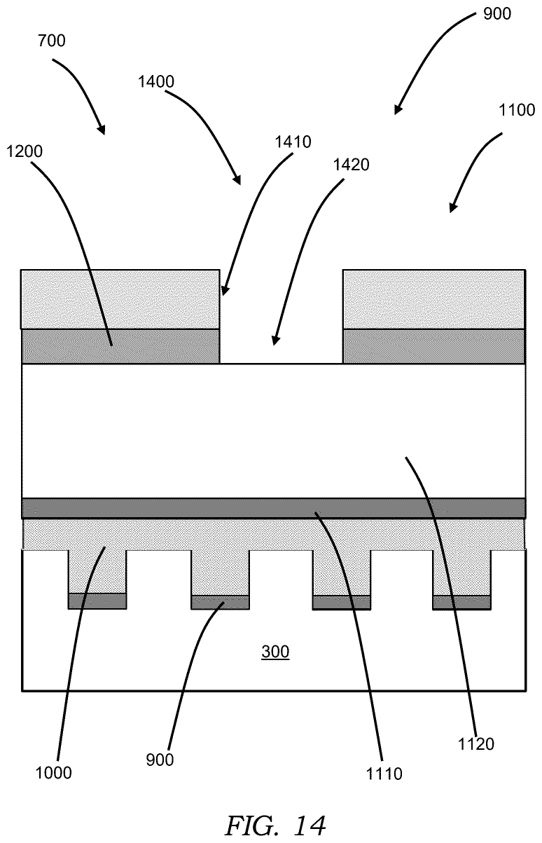

FIG. 14 is an illustration of an opening 1400 formed in epitaxial layer 1120 in accordance with an example embodiment. Opening 1400 forms a trench that removes a portion of body implant layer 1300 and a portion of current spreading layer 1200. The trench formed by opening 1400 has a bottom 1420 and walls 1410. In the example embodiment, opening 1400 has walls 1410 that is vertical and bottom 1420 that is substantially planar. In the example embodiment, opening 1400 is formed by patterning and etching a portion of body implant layer 1300 and a portion of current spreading layer 1200 by using lithography to define the pattern and using RIE (Reactive Ion Etching) to form the trench to expose a portion of epitaxial layer 1120. In one embodiment, opening 1400 may be formed by deposition a hard mask, patterning the hard mask to expose surface of body implant layer 1300 and then using RIE to remove a portion of body implant layer 1300 and current spreading layer 1200 to expose a surface of epitaxial layer 1120. The hard mask layer is then removed after opening 1400 is formed.

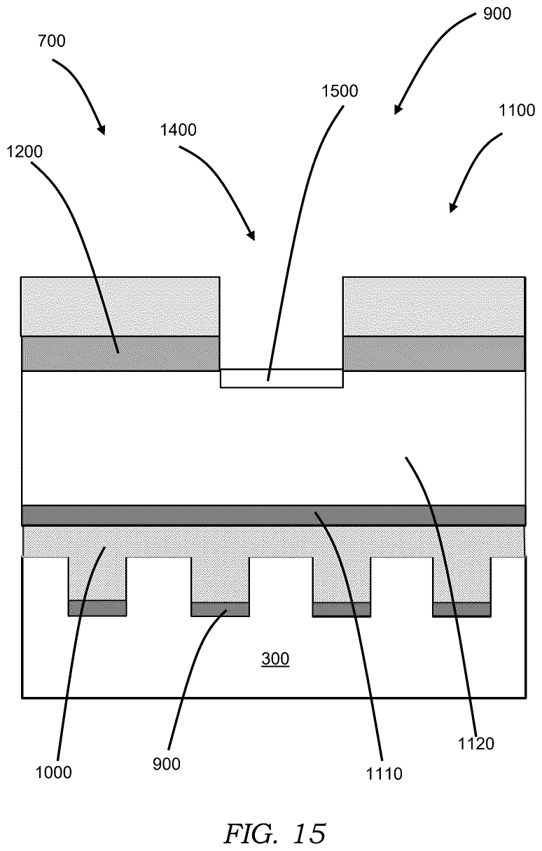

FIG. 15 is an illustration of an implant layer 1500 formed on bottom 1420 of the trench in accordance with an example embodiment. Implant layer 1500 is formed by implanting dopants of an opposite polarity of epitaxial layer 1120. In the example embodiment, epitaxial layer 1120 is n-doped and implant layer 1500 is p-doped. Implant layer 1500 is a shield layer formed to improve the electrical performance of the trench MOSFET of the IGBT that is formed in subsequent fabrication steps.

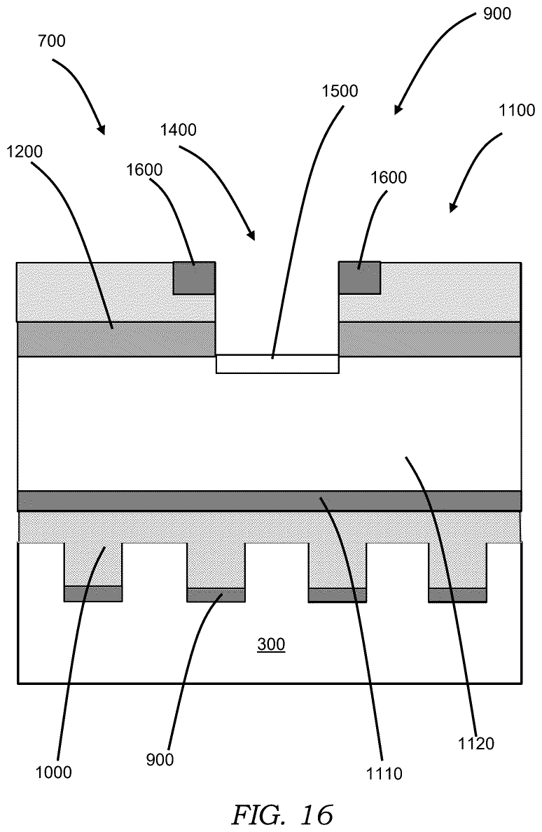

FIG. 16 is an illustration of source regions 1600 formed in body implant layer 1300 in accordance with an example embodiment. Source regions 1600 are selectively formed in body implant layer 1300 by implanting dopants through a mask that are of the opposite polarity than body implant layer 1300. Source regions 1600 formed in body implant layer 1300 serve as the source electrode of a MOSFET of the IGBT that is formed in subsequent fabrication steps. In one embodiment, source regions 1600 are formed by implanting n-type dopants through a mask into body implant layer 1300 that is doped p-type.

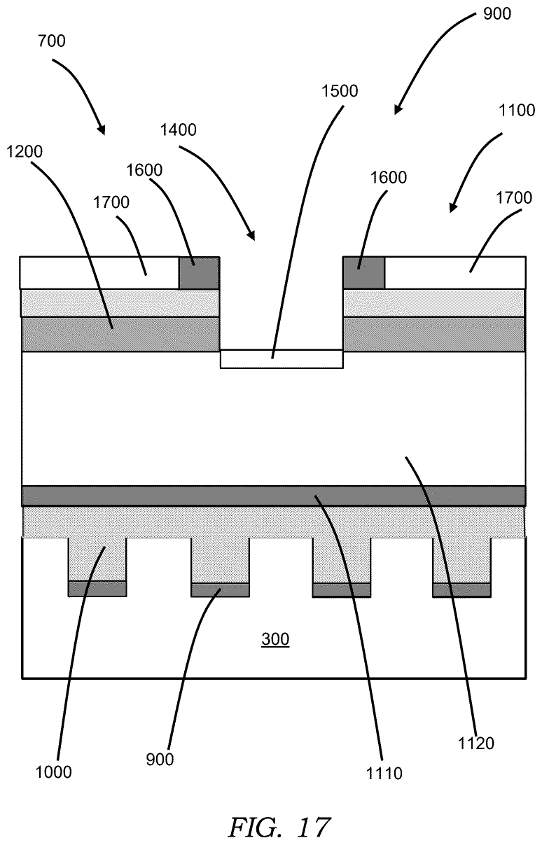

FIG. 17 is an illustration of an implant layer 1700 formed adjacent to source regions 1600 in accordance with an example embodiment. Implant layer 1700 is formed by implanting dopants through a mask that has a polarity that is opposite to that of source regions 1600. In an example embodiment, implant layer 1700 is formed by implanting p-type dopants adjacent to source regions 1600 that are doped n-type in a MOSFET of an IGBT that is formed in subsequent fabrication steps.

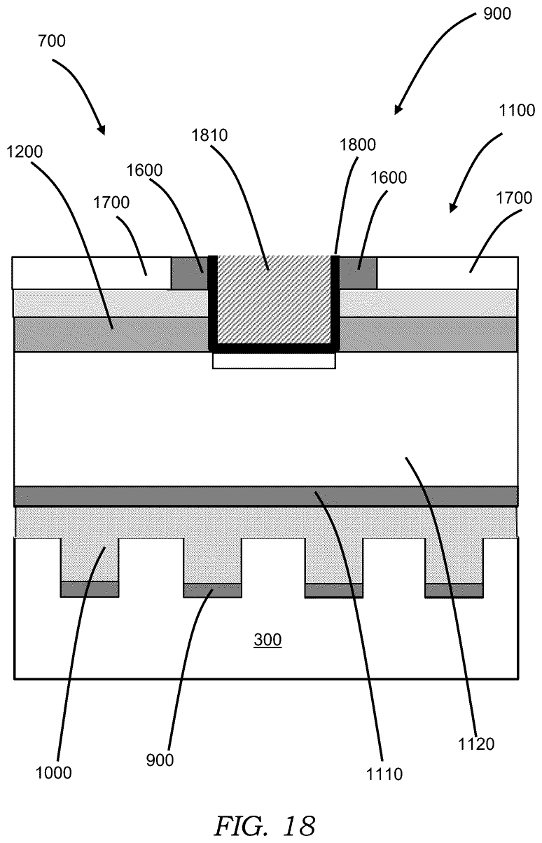

FIG. 18 is an illustration of a gate oxide 1800 and a gate electrode 1810 formed in accordance with an example embodiment. In the example embodiment, gate oxide 1800 is formed in walls 1410 of the trench formed in opening 1400 of FIG. 17 and is also formed on bottom 1420 of the trench. In one embodiment, gate oxide 1800 is formed by deposition. The thickness of gate oxide 1800 is (200-500) Angstroms and may be composed of one or more layers of gate dielectric materials. In one embodiment, gate electrode 1810 is formed by depositing a gate electrode layer that is electrically conducting. In one embodiment, gate electrode 1810 is formed by depositing doped LPCVD polysilicon overlying gate oxide 1800. The LPCVD polysilicon layer forming gate electrode 1810 may be doped n-type or p-type The thickness of gate electrode 1810 is chosen to completely refill opening 1400 and may be in the range of (0.3-2) micrometers. Portions of layer of gate electrode 1810 deposited on a surface of source regions 1600 and a surface of implant layer 1700 are subsequently removed. In the example embodiment, the surfaces of source regions 1600 and implant layer 1500 are substantially planar to a surface of gate electrode 1810. The removal of portions of layer of gate electrode 1810 deposited on surface of source regions 1600 and implant layer 1700 may be done using CMP or by RIE.

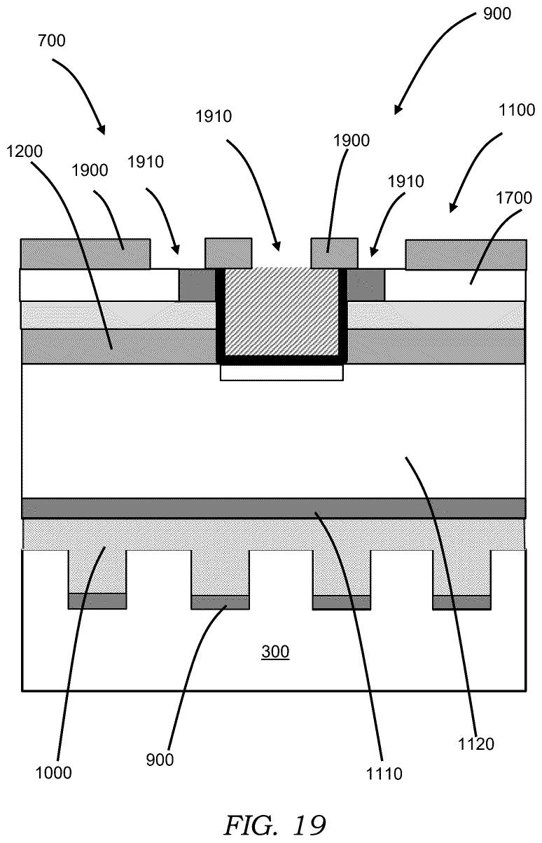

FIG. 19 is an illustration of a dielectric isolation layer 1900 with a plurality of contact openings 1910 in accordance with an example embodiment. Dielectric isolation layer 1900 is deposited by using PECVD Silicon Dioxide, PECVD Silicon Nitride, PECVD, or Silicon Oxynitride among other films. In one embodiment, the thickness of dielectric isolation layer 1900 is in a range of (1-4) micrometers. In an example embodiment, dielectric isolation layer 1900 is PECVD Silicon Oxide and is approximately one micrometer thick. In one embodiment, dielectric isolation layer 1900 is formed by oxidation of the layer of gate electrode 1810 of FIG. 18 formed by deposition of doped LPCVD polysilicon. In another embodiment, dielectric isolation layer 1900 may be formed by deposition of multiple layers of dielectric isolation layers.

In FIG. 19, dielectric isolation layer 1900 is patterned and etched to form plurality of contact openings 1910. In the example embodiment, dielectric isolation layer 1900 is patterned and etched to form openings 1910 so as to enable contact with the source and gate of the MOSFET.

In one embodiment, photolithography techniques and etching of dielectric isolation layer 1900 to form contact openings 1910 are done using RIE (Reactive Ion Etching), wet etching or a combination of etching steps. In an example embodiment, contact openings 1910 are patterned using a stepper and etched using RIE.

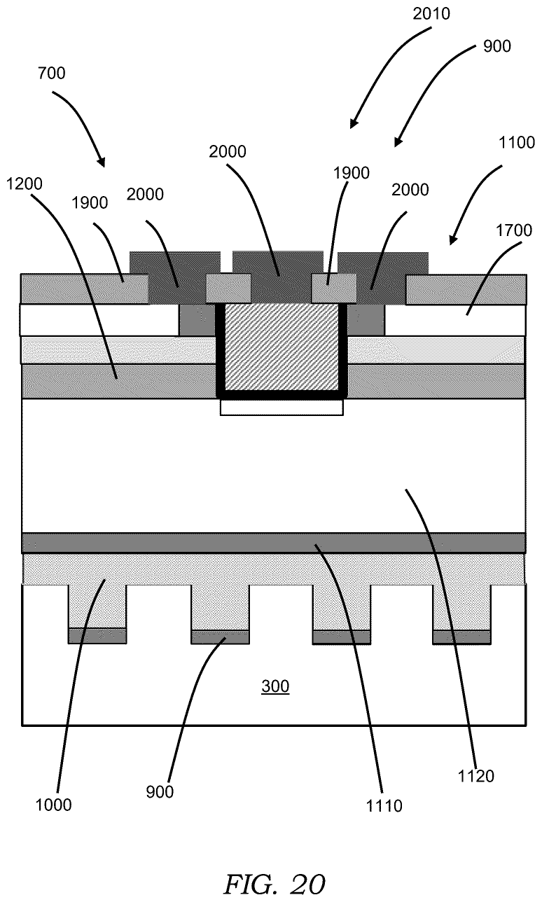

FIG. 20 is an illustration of a plurality of metal contacts 2000 formed in accordance with an example embodiment. In the example embodiment, metal contacts 2000 are meant to enable electrical connections to the source and gate electrodes of the MOSFET. Metal contacts 2000 makes electrical contact with source regions 1600 and gate electrode 1810. Metal contacts 2000 can be formed by deposition of a metal layer using sputtering, e-beam evaporation, electrodeposition among other techniques and can also use a combination of metal deposition techniques. The metal layer may be patterned using lithography and etched to form metal contacts 2000.

In addition, lift-off techniques may also be used for the deposition and patterning of the metal layer to form metal contacts 2000, as will be evident to those skilled in the art. The metal layer forming metal contacts 2000 may be annealed or sintered to ensure good ohmic contact with source and gate regions of the MOSFET.

After formation of metal contacts 2000, a passivation layer may be deposited and patterned to expose bond pads of gate and source electrodes of the MOSFET. At this stage, in the example embodiment, the fabrication of an IGBT 2010 with improved electrical performance is complete where a MOSFET is electrically coupled with a BJT using the fabrication process described in FIGS. 3-20). In the example embodiment, while the implementation of a single IGBT is described, it will be understood by those skilled in the art that a plurality of IGBTs can be formed in an array on silicon carbide substrate 300 using the same fabrication processes.

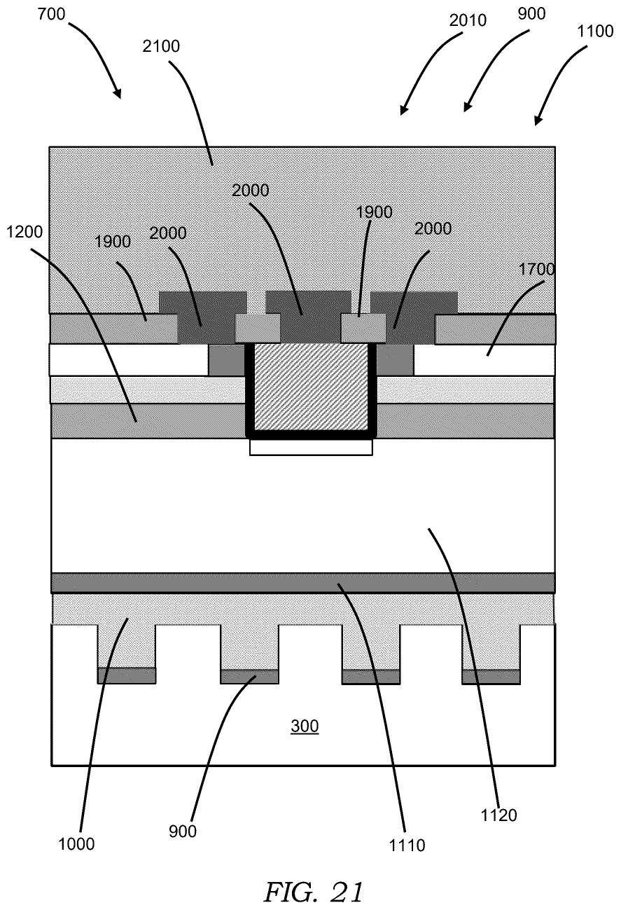

FIG. 21 is an illustration of a carrier wafer 2100 attached to IGBT 2010 formed in silicon carbide substrate 300 in accordance with an example embodiment. Silicon carbide substrate 300 with IGBT 2010 is temporarily coupled to carrier wafer 2100 to enable an exfoliation process which is subsequently described. The exfoliation process enables the separation of a portion of silicon carbide substrate 300 with IGBT 2010 to be separated from the major portion of silicon carbide substrate 300.

In one embodiment, silicon carbide substrate 300 with IGBT 2010 is attached to carrier wafer 2100 by adhesives such as UV sensitive glue among others. Carrier wafer 2100 may be borosilicate glass which is UV transparent and may be used with a UV curable adhesive for the bonding.

The exfoliation process occurs at an exfoliation layer comprising plurality of pillars 700 from FIG. 7 and mask layer 900 of FIG. 9. Mask layer 900 is between plurality of pillars 700 of FIG. 7 in silicon carbide substrate 300. IGBT 2010 is formed in epitaxial layer 1100 overlying merge layer 1000. In one embodiment, a plane of the exfoliating layer is below a top surface of plurality of pillars 700 of FIG. 7 and on a plane corresponding to mask layer 900. In the example embodiment, the plane of exfoliation will occur at approximately mask layer 900 of FIG. 9 such that substrate 300 has a new surface below the previous surface in which the plurality of pillars 700 of FIG. 7 are formed.

Different methods of exfoliation may be used to separate a portion of silicon carbide substrate 300 with IGBT 2010 from a major portion of silicon carbide substrate 300. In an example embodiment, a laser may be used for the exfoliation. In the example embodiment, a laser that is substantially transparent to Silicon Carbide is focused though the backside of substrate 300 on the mask layer 900. As previously mentioned, the exfoliation layer comprises plurality of pillars 700 from FIG. 7 and mask layer 900 between plurality of pillars 700 of FIG. 7 in silicon carbide substrate 300. In the example embodiment, mask layer 900 comprises carbon. The energy from the laser is selectively coupled to mask layer 900 comprising carbon between plurality of pillars 700 in silicon carbide substrate 300. In one embodiment, the laser rapidly heats the carbon of mask layer 900 thereby producing a thermal shock that fractures pillars adjacent to the heated carbon of plurality of pillars 700 of FIG. 7 in silicon carbide substrate 300. The fracture in plurality of pillars 700 of FIG. 7 due to thermal shock causes a portion of silicon carbide substrate 300 with IGBT 2010 to be exfoliated from the major portion of silicon carbide substrate 300.

In the example embodiment, as a result of the exfoliation process, IGBT 2010 formed in epitaxial layer 1100, along with merge layer 1000, and a portion of silicon carbide substrate 300 above mask layer 900 will remain with carrier wafer 2100. Thus, the major portion of silicon carbide substrate 300 is physically separated from IGBT 2010 by the exfoliation process.

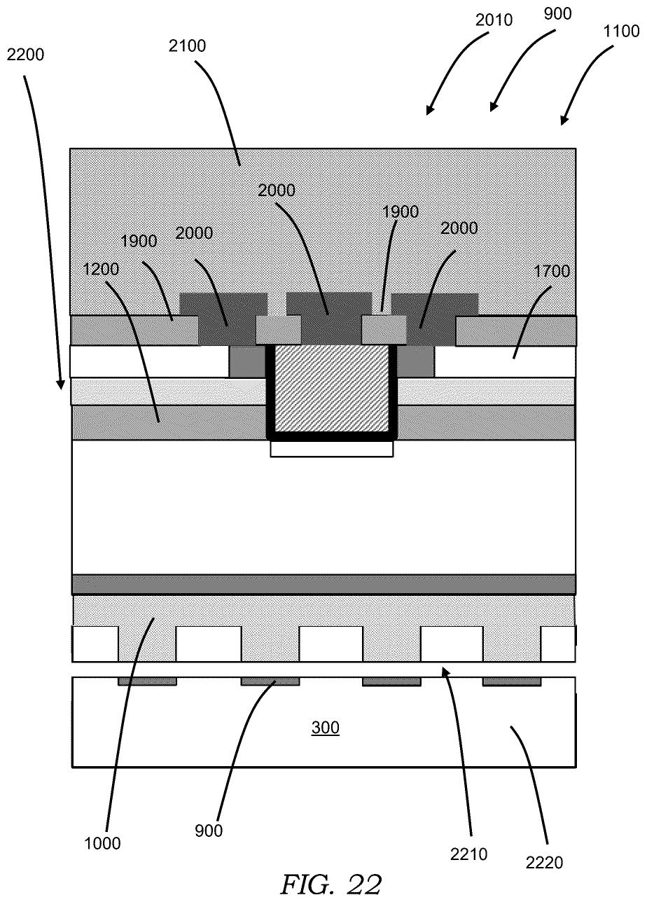

FIG. 22 is an illustration of a portion of silicon carbide substrate 2200 after the exfoliation process in accordance with an example embodiment. In the example embodiment, the separation of silicon carbide substrate 2200 using a laser causes a fracture plane 2210 leaving IGBT 2010 and the portion of silicon carbide substrate 300 coupled with carrier wafer 2100 and the major portion of silicon carbide substrate 300 separated below fracture plane 2210.

In the example embodiment, silicon carbide substrate 2200 comprises IGBT 2010 formed in silicon carbide epitaxial layer 1100 overlying silicon carbide merge layer 1000. Thus, silicon carbide substrate 2200 comprises primarily of silicon carbide epitaxial layers grown in an epitaxial reactor and is temporarily coupled to carrier wafer 2100 for the exfoliating process. Silicon carbide substrate 2225 comprises the major portion of silicon carbide substrate 300 remaining after the exfoliation process. Silicon carbide substrate 2225 is then subsequently processed for re-use for formation of semiconductor devices such as IGBTs two or more times.

In general, fracture plane 2210 is substantially in the same plane where mask layer 900 of FIG. 9 is formed between plurality of pillars 700 from FIG. 7 and is substantially planar to the surface of silicon carbide substrate 300 of FIG. 3. FIG. 22 is not drawn to scale since thickness of remaining silicon carbide substrate 2225 is in the range of 300-400 micrometers, while the portion of silicon carbide substrate 2200 is in the range of 20-150 micrometers, depending on the thickness of epitaxial layer 1100 that is grown to form the IGBT. As mentioned previously, typically more than one IGBT is formed in silicon carbide substrate 300.

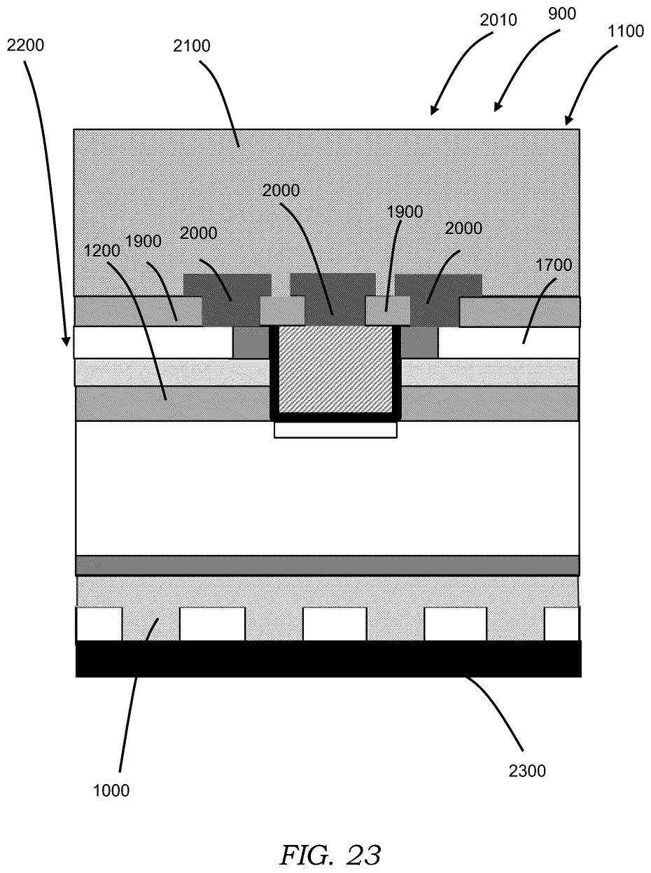

FIG. 23 is an illustration of a back metal layer 2300 deposited in accordance with an example embodiment. In the example embodiment, back metal layer 2300 is deposited on backside of silicon carbide substrate 2200 with IGBT 2010 attached to carrier wafer 2100. After the exfoliation process, the exposed surface of silicon carbide substrate 2200 with IGBT 2010 attached to carrier wafer 2100 is polished to remove any remnants of plurality of pillars 700 of FIG. 7 and mask layer 900 of FIG. 9. The cleaned and polished surface of silicon carbide substrate 2200 with IGBT 2010 attached to carrier wafer 2100 is coated with back metal layer 2300 to form the collector electrode of the BJT of IGBT 2010.

Back metal layer 2300 is deposited using evaporation, sputtering and other methods of metal deposition. Metals such as nickel, or combination of metals such as Ti/Ni/Au (Titanium/Nickel/Gold) may be used along with annealing to reduce contact resistance to the surface of silicon carbide substrate 2200. In one embodiment, laser annealing may be used to reduce contact resistance of back metal layer 2300.

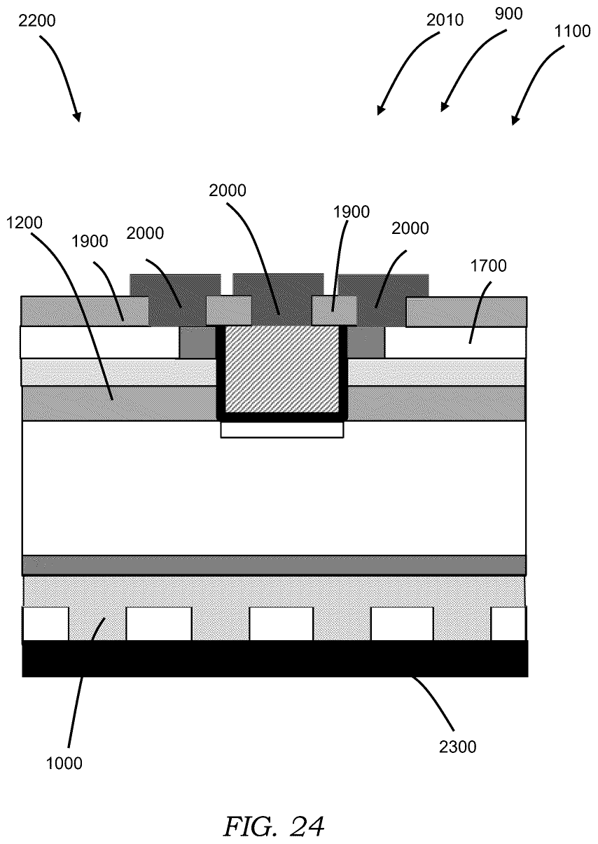

FIG. 24 is an illustration of silicon carbide substrate 2200 with IGBT 2010 after being separated from carrier wafer 2100 in accordance with an example embodiment.

It should be noted that although a single IGBT is shown fabricated on silicon carbide substrate 2200 in the example embodiment, other IGBTs will be formed simultaneously in silicon carbide substrate 2200. Typically, silicon carbide substrate 2200 can be used to form hundreds and thousands of IGBTs simultaneously, depending on the size of initial silicon carbide substrate 300 of FIG. 3. In one embodiment, the IGBTs formed in silicon carbide substrate 2200 will be diced and packaged.

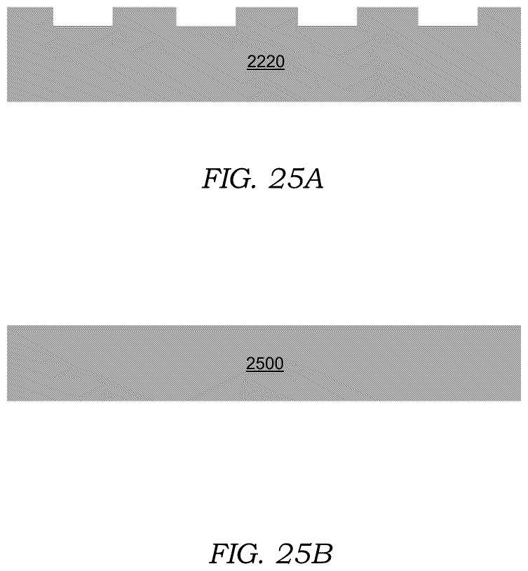

FIG. 25A is an illustration of silicon carbide substrate 2225 after exfoliation in accordance with an example embodiment. As previously disclosed, silicon carbide substrate 2225 is the major portion of silicon carbide substrate 300 of FIG. 3 after the exfoliation process. Silicon carbide substrate 2225 is reclaimed by re-polishing the surface exposed to fracture plane 2210 of FIG. 22 such that a polished surface is produced that can be used in the formation of semiconductor devices.

In one embodiment, the polishing of the surface of silicon carbide substrate 2225 of FIG. 22 is performed using CMP (chemical mechanical planarization), electrochemical polishing among other methods.

FIG. 25B is an illustration of a reclaimed silicon carbide substrate 2500 in accordance with an example embodiment. Reclaimed silicon carbide substrate 2500 is produced by the polishing of the surface of silicon carbide substrate 2220 of FIG. 22 such that it can be successively re-used for formation of semiconductor devices such as IGBTs.

By the successive application of the current invention as described by the example embodiment, the same original silicon carbide substrate 300 of FIG. 3 can be used for fabrication of silicon carbide semiconductor devices multiple times leading to significant reduction in the cost of fabrication of silicon carbide semiconductor devices. Reclaimed silicon carbide substrate 2500 can be used for successive formation of semiconductor devices using the same silicon carbide substrate 300 of FIG. 3 but with a portion removed by each subsequent exfoliation process.

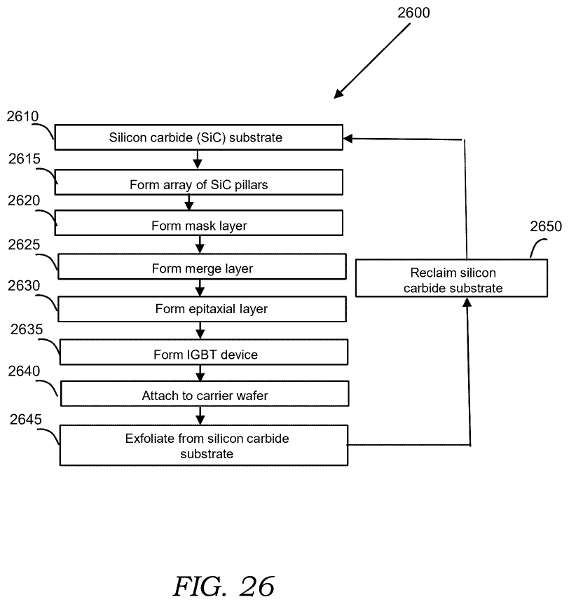

FIG. 26 is an illustration showing a block diagram 2600 of the formation of an IGBT in accordance with an example embodiment. Block diagram 2600 shows the major fabrication steps in the formation of an IGBT and re-use of the silicon carbide substrate in accordance with an example embodiment. The order of the blocks in block diagram 2600 in FIG. 26 is for illustrative purposes only and does not imply an order or show all the specific steps in the implementation of the invention as are known by one skilled in the art.

In block diagram 2600, block 2610 illustrates the silicon carbide substrate used to form the IGBT in an example embodiment. In block 2615, a plurality of pillars are formed in silicon carbide substrate and a mask layer is formed between the plurality of pillars as shown in block 2620. Block 2625 shows the formation of a merge layer formed by lateral epitaxial overgrowth that has low concentration of defects such as basal plane dislocations. Block 2630 shows the epitaxial layer grown above the merge layer that also has a high quality (meaning low concentration of defects) and is suitable for formation of high voltage devices such as IGBTs. The epitaxial layer shown in block 2630 may comprise one or more layers that are grown by epitaxy. Block 2635 shows the formation of an IGBT using the epitaxial layer shown in block 2630. The details of formation of an IGBT are disclosed in detail herein above. After the IGBT is formed, the substrate is attached to a carrier wafer, as shown in block 2640. Block 2645 shows the exfoliation of the major portion of the silicon carbide substrate after formation of the IGBT, which is then reclaimed and reused multiple times, as shown in block 2650.

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

The descriptions disclosed herein below will call out components, materials, inputs, or outputs from FIGS. 1-26.

In one embodiment, a plurality of IGBTs (insulated gate bipolar transistors) 2010 comprises a silicon carbide (SiC) substrate 300, a merge layer 1000 formed in silicon carbide substrate 300 wherein merge layer 1000 comprises an epitaxial layer formed by on-axis epitaxial lateral overgrowth and at least one epitaxial 1100 layer formed overlying merge layer 1000 wherein plurality of IGBTs 2010 are formed in or overlying at least one epitaxial layer 1100 and wherein an exfoliation process is configured to separate silicon carbide substrate 300 at merge layer 1000 from at least one epitaxial layer 1100 such that silicon carbide substrate 300 can be reused for subsequent device manufacture.

In one embodiment, plurality of IGBTs 2010 comprising silicon carbide substrate 300 wherein silicon carbide substrate 300 is <1120> crystal.

In one embodiment, plurality of IGBTs 2010 comprising at least one epitaxial layer 1100 has a defectivity less than 104 defects per square centimeter.

In one embodiment, plurality of IGBTs 2010 comprising an epitaxial layer wherein the epitaxial layer of at least one epitaxial layer 1100 is greater than 50 microns thick.

In one embodiment, plurality of IGBTs 2010 comprising merge layer 1000 comprising a plurality of pillars 700 formed in silicon carbide substrate 300 and a mask layer 900 formed between plurality of pillars 700 wherein the on-axis lateral epitaxial overgrowth is configured to extend from sidewalls of plurality of pillars 700 above mask layer 900 and wherein silicon carbide substrate 300 and the epitaxial layer of merge layer 1000 is of a first type.

In one embodiment, plurality of IGBTs 2010 comprising mask layer 900 comprising carbon or tantalum carbide, wherein mask layer 900 is heated by at least one laser, and wherein heating mask layer 900 is configured to fracture plurality of pillars 700 by thermal shock to initiate separation of silicon carbide substrate 300.

In one embodiment, plurality of IGBTs 2010 wherein the on-axis epitaxial overgrowth from adjacent pillars of plurality of pillars 700 is configured to merge, wherein a surface of the on-axis epitaxial overgrowth and the top surfaces of plurality of pillars 700 forms a continuous silicon carbide surface on which at least one epitaxial layer 1100 is formed.

In one embodiment, plurality of IGBTs 2010 wherein an IGBT of the plurality of IGBT comprises a MOSFET coupled to a bipolar transistor.

In one embodiment, plurality of IGBTs 2010 wherein at least one epitaxial layer 1100 comprises a first epitaxial layer 1110 of a second type overlying merge layer 1000 and a second epitaxial layer 1120 of the second type overlying first epitaxial layer 1110 wherein first epitaxial layer 1120 has a doping greater than second epitaxial layer 1120, wherein second epitaxial layer 1120 has the defectivity less than 104 defects per square centimeter.

In one embodiment, plurality of IGBTs 2010 wherein silicon carbide substrate 300 is prepared for reuse after the exfoliation process such that one or more devices can be formed in or overlying the prepared surface of silicon carbide substrate 300.

In one embodiment, plurality of IGBTs (insulated gate bipolar transistors) comprises a 4H silicon carbide (SiC) A-plane <1120> substrate of a first type, a 4H silicon carbide (SiC) A-plane <1120> substrate of a first type, plurality of pillars 700 formed in the 4H silicon carbide A-plane <1120> substrate wherein each pillar of plurality of pillars 700 has a top surface, mask layer 900 formed between plurality of pillars 700, a first epitaxial layer of the first type formed by epitaxial lateral overgrowth wherein the first epitaxial layer extends from sidewalls of plurality of pillars 700 and wherein the epitaxial lateral overgrowth overlies mask layer 900 thereby providing a surface comprising the epitaxial lateral overgrowth or the top surface of each pillar of plurality of pillars 700, a second epitaxial layer of a second type, a third epitaxial layer of the second type wherein the second and third epitaxial layer are formed by vertical epitaxial overgrowth, wherein the second epitaxial layer has a doping greater than the third epitaxial layer, and wherein the third epitaxial layer is greater than 25 microns thick, and plurality of IGBTs 2010 formed in or overlying the third epitaxial layer wherein the third epitaxial layer is a drift layer for the plurality of IGBTs, wherein the third epitaxial layer has a defectivity less than 104 defects per square centimeter, and wherein mask layer 900 is configured to be heated to exfoliate the 4H silicon carbide (SiC) A-plane <1120> substrate from plurality of IGBTs 2010 by thermal shock.

In one embodiment, plurality of IGBTs (insulated gate bipolar transistors) 2010 wherein the 4H silicon carbide (SiC) A-plane <1120> substrate is separated from plurality of IGBTs 2010.

In one embodiment, plurality of IGBTs (insulated gate bipolar transistors) 2010 wherein the third epitaxial layer is greater than 50 microns thick.

In one embodiment, plurality of IGBTs (insulated gate bipolar transistors) 2010 wherein the defectivity is less than 104 defects per square centimeter.

In one embodiment, plurality of IGBTs (insulated gate bipolar transistors) 2010 wherein the 4H silicon carbide (SiC) A-plane <1120> substrate silicon carbide substrate is prepared for reuse after an exfoliation process such that one or more devices can be formed in or overlying a prepared 4H silicon carbide (SiC) A-plane <1120> substrate surface and wherein preparation includes chemical mechanical planarization.

In one embodiment, a method of forming a plurality of IGBTs (insulated gate bipolar transistors) 2010 comprises the steps of providing a 4H silicon carbide (SiC) A-plane <1120> substrate of a first type, etching a plurality of pillars 700 formed in the 4H silicon carbide A-plane <1120> substrate wherein each pillar of plurality of pillars 700 has a top surface, depositing a mask layer 900 between plurality of pillars 700, growing a first epitaxial layer of the first type by epitaxial lateral overgrowth wherein the first epitaxial layer extends from sidewalls of plurality of pillars 700, growing at least one epitaxial layer greater than 25 microns thick of a second type by vertical epitaxial overgrowth, and forming plurality of IGBTs 2010 in or overlying the at least one epitaxial layer greater than 25 microns thick wherein the at least one epitaxial layer greater than 25 microns thick is a drift layer for plurality of IGBTs 2010, wherein the at least one epitaxial layer greater than 25 microns thick has a defectivity less than 104 defects per square centimeter, and wherein mask layer 900 is configured to be heated to exfoliate the 4H silicon carbide (SiC) A-plane <1120> substrate from plurality of IGBTs 2010 by thermal shock.

In one embodiment, the method of plurality of IGBTs (insulated gate bipolar transistors) 2010 further includes forming a surface comprising the first epitaxial layer or the top surface of each pillar of plurality of pillars 700 and growing the at least one epitaxial layer greater than 25 microns thick overlying the surface to minimize Basal-Plane-Dislocations (BPDs) in the drift layer for IGBTs operating at greater than 2500 volts.

In one embodiment, the method of forming plurality of IGBTs (insulated gate bipolar transistors) 2010 further includes growing a second epitaxial layer of a second type overlying the first epitaxial layer and growing a third epitaxial layer of the second type overlying the second epitaxial layer wherein the second and third epitaxial layer are formed by vertical epitaxial overgrowth, wherein the third epitaxial has a doping greater than the third epitaxial layer, and wherein the third epitaxial layer is greater than 25 microns thick

In one embodiment, the method of forming plurality of IGBTs (insulated gate bipolar transistors) 2010 further includes heating mask layer 900 using one or more lasers wherein heat from mask layer 900 produces a thermal shock to plurality of pillars 700 and separating the 4H silicon carbide (SiC) A-plane <1120> substrate from plurality of IGBTs 2010.

In one embodiment, the method of forming plurality of IGBTs (insulated gate bipolar transistors) 2010 further includes preparing the 4H silicon carbide (SiC) A-plane <1120> substrate for reuse wherein a surface of the 4H silicon carbide (SiC) A-plane <1120> substrate is planarized prior to reuse to form subsequent devices.

What is claimed:

1. A plurality of IGBTs (insulated gate bipolar transistors) comprising:
a silicon carbide (SiC) substrate;
a merge layer formed in the silicon carbide substrate wherein the merge layer comprises an epitaxial layer formed by on-axis epitaxial lateral overgrowth; and
at least one epitaxial layer formed overlying the merge layer wherein the plurality of IGBTs are formed in or overlying the at least one epitaxial layer and wherein an exfoliation process is configured to separate the silicon carbide substrate at the merge layer from the at least one epitaxial layer such that the silicon carbide substrate can be reused for subsequent device manufacture.

2. The plurality of IGBTs of claim 1 wherein the silicon carbide substrate is <1120> crystal.

3. The plurality of IGBTs of claim 2 wherein the at least one epitaxial layer has a defectivity less than 10⁴ defects per square centimeter.

4. The plurality of IGBTs of claim 3 wherein an epitaxial layer of the at least one epitaxial layer is greater than 50 microns thick.

5. The plurality of IGBTs of claim 2 wherein the merge layer comprises:
a plurality of pillars formed in the silicon carbide substrate; and
a mask layer formed between the plurality of pillars wherein the on-axis lateral epitaxial overgrowth is configured to extend from sidewalls of the plurality of pillars above the mask layer and wherein the silicon carbide substrate and the epitaxial layer of the merge layer is of a first type.

6. The plurality of IGBTs of claim 5 wherein the mask layer comprises carbon or tantalum carbide, wherein the mask layer is heated by at least one laser, and wherein heating the mask layer is configured to fracture the plurality of pillars by thermal shock to initiate separation of the silicon carbide substrate.

7. The plurality of IGBTs of claim 5 wherein the on-axis epitaxial overgrowth from adjacent pillars of the plurality of pillars is configured to merge, wherein a surface of the on-axis epitaxial overgrowth and the top surfaces of the plurality of pillars forms a continuous silicon carbide surface on which the at least one epitaxial layer is formed.

8. The plurality of IGBTs of claim 5 wherein an IGBT of the plurality of IGBT comprises a MOSFET coupled to a bipolar transistor.

9. The plurality of IGBTs of claim 8 wherein the at least one epitaxial layer comprises:
a first epitaxial layer of a second type overlying the merge layer; and
a second epitaxial layer of the second type overlying the first epitaxial layer wherein the first epitaxial layer has a doping greater than the second epitaxial layer, wherein the second epitaxial layer has the defectivity less than 10⁴ defects per square centimeter.

10. The plurality of IGBTs of claim 9 wherein the silicon carbide substrate is prepared for reuse after the exfoliation process such that one or more devices can be formed in or overlying the prepared surface of the silicon carbide substrate.

11. A plurality of IGBTs (insulated gate bipolar transistors) comprising:
a 4H silicon carbide (SiC) A-plane <1120> substrate of a first type;
a plurality of pillars formed in the 4H silicon carbide A-plane <1120> substrate wherein each pillar of the plurality of pillars has a top surface;
a mask layer formed between the plurality of pillars;
a first epitaxial layer of the first type formed by epitaxial lateral overgrowth wherein the first epitaxial layer extends from sidewalls of the plurality of pillars and wherein the epitaxial lateral overgrowth overlies the mask layer thereby providing a surface comprising the epitaxial lateral overgrowth or the top surface of each pillar of the plurality of pillars;
a second epitaxial layer of a second type;
a third epitaxial layer of the second type wherein the second and third epitaxial layer are formed by vertical epitaxial overgrowth, wherein the second epitaxial layer has a doping greater than the third epitaxial layer, and wherein the third epitaxial layer is greater than 25 microns thick; and
the plurality of IGBTs formed in or overlying the third epitaxial layer wherein the third epitaxial layer is a drift layer for the plurality of IGBTs, wherein the third epitaxial layer has a defectivity less than 10⁴ defects per square centimeter, and wherein the mask layer is configured to be heated to exfoliate the 4H silicon carbide (SiC) A-plane <1120> substrate from the plurality of IGBTs by thermal shock.

12. The plurality of IGBTs (insulated gate bipolar transistors) of claim 11 wherein the 4H silicon carbide (SiC) A-plane <1120> substrate is separated from the plurality of IGBTs.

13. The plurality of IGBTs (insulated gate bipolar transistors) of claim 11 wherein the third epitaxial layer is greater than 50 microns thick.

14. The plurality of IGBTs (insulated gate bipolar transistors) of claim 11 wherein the defectivity less than 10⁴ defects per square centimeter.

15. The plurality of IGBTs (insulated gate bipolar transistors) of claim 11 wherein the 4H silicon carbide (SiC) A-plane <1120> substrate silicon carbide substrate is prepared for reuse after an exfoliation process such that one or more devices can be formed in or overlying a prepared 4H silicon carbide (SiC) A-plane <1120> substrate surface and wherein preparation includes chemical mechanical planarization.

16. A method of forming a plurality of IGBTs (insulated gate bipolar transistors) comprising the steps of:
providing a 4H silicon carbide (SiC) A-plane <1120> substrate of a first type;
etching a plurality of pillars formed in the 4H silicon carbide A-plane <1120> substrate wherein each pillar of the plurality of pillars has a top surface;
depositing a mask layer between the plurality of pillars;
growing a first epitaxial layer of the first type by epitaxial lateral overgrowth wherein the first epitaxial layer extends from sidewalls of the plurality of pillars;
growing at least one epitaxial layer greater than 25 microns thick of a second type by vertical epitaxial overgrowth; and
forming the plurality of IGBTs in or overlying the at least one epitaxial layer greater than 25 microns thick wherein the at least one epitaxial layer greater than 25 microns thick is a drift layer for the plurality of IGBTs, wherein the at least one epitaxial layer greater than 25 microns thick has a defectivity less than 10⁴ defects per square centimeter, and wherein the mask layer is configured to be heated to exfoliate the 4H silicon carbide (SiC) A-plane <1120> substrate from the plurality of IGBTs by thermal shock.

17. The method of forming a plurality of IGBTs (insulated gate bipolar transistors) of claim 16 further including:
forming a surface comprising the first epitaxial layer or the top surface of each pillar of the plurality of pillars; and
growing the at least one epitaxial layer greater than 25 microns thick overlying the surface to minimize Basil-Plane-Dislocations (BPDs) in the drift layer for IGBTs operating at greater than 2500 volts.

18. The method of forming a plurality of IGBTs (insulated gate bipolar transistors) of claim 17 further including:
growing a second epitaxial layer of a second type overlying the first epitaxial layer; and
growing a third epitaxial layer of the second type overlying the second epitaxial layer wherein the second and third epitaxial layer are formed by vertical epitaxial overgrowth, wherein the third epitaxial has a doping greater than the third epitaxial layer, and wherein the third epitaxial layer is greater than 25 microns thick.

19. The method of forming a plurality of IGBTs (insulated gate bipolar transistors) of claim 16 further including:
heating the mask layer using one or more lasers wherein heat from the mask layer produces a thermal shock to the plurality of pillars; and
separating the 4H silicon carbide (SiC) A-plane <1120> substrate from the plurality of IGBTs.

20. The method of forming a plurality of IGBTs (insulated gate bipolar transistors) of claim 19 further including preparing the 4H silicon carbide (SiC) A-plane <1120> substrate for reuse wherein a surface of the 4H silicon carbide (SiC) A-plane <1120> substrate is planarized prior to reuse to form subsequent devices.
